(19) United States
(12) Patent Application Publication
(10) Pub. No.: US 2015/0096719 A1
(43) Pub. Date: Apr. 9, 2015

(54) Apparatus for Dissipating Heat

(71) Applicant: Specialty Minerals (Michigan) Inc., Bingham Farms, MI (US)

(72) Inventors: Robert John Moskaitis, Easton, PA (US); Mark Breloff, Center Valley, PA (US)

(21) Appl. No.: 14/046,016

(22) Filed: Oct. 4, 2013

(51) Int. Cl. H05K 7/20

(52) U.S. Cl. CPC H05K 7/20254; H05K 7/20272
USPC 165/80.4; 165/104.19; 165/104.31

(57) ABSTRACT

An apparatus for dissipating heat includes a plate or pipe made of a planar thermal conductive material, such as pyrolytic graphite. The apparatus may include fins attached to the plate or pipe, and the fins can be made of the same or different material as the plate or pipe.

### FIELD OF THE INVENTION

The present invention relates to an apparatus for dissipating heat, and more particularly to cold plates and cooling tubes.

### BACKGROUND OF THE INVENTION

Miniaturization, increased complexity and/or increased functional capacity of various devices, such as electronic assemblies and individual components, often results in more heat being generated which must be dissipated to maintain performance and avoid damage. Conventional methods for dissipating heat may fail to satisfy cooling requirements and design constraints relating to physical size, weight, power consumption, cost, or other parameters. Accordingly, there is a continuing need for an efficient means for dissipating heat from a variety of heat sources.

### SUMMARY OF THE INVENTION

Briefly and in general terms, the present invention is directed to an apparatus for dissipating heat.

In aspects of the present invention, an apparatus comprises a plate made of a planar thermal conductive material. The plate includes a top layer and a bottom layer. Each of the top and bottom layers is oriented in an x-direction and a y-direction coplanar with the x-direction. There is at least one fluid passageway formed through the plate and disposed between the top layer and the bottom layer. The at least one fluid passageway is configured to transport a fluid.

Any one or a combination of two or more of the following features can be appended to the aspect above to form additional aspects of the invention.

The top layer is made of the planar thermal conductive material.

The bottom layer is made of the planar thermal conductive material.

The plate includes an intermediate layer between the top layer and the bottom layer, the intermediate layer is made of the planar thermal conductive material, and the at least one fluid passageway extends through the intermediate layer.

The planar thermal conductive material is pyrolytic graphite.

The apparatus further comprises fins on the plate.

The at least one fluid passageway is oriented in the y-direction, the plate has a first thermal conductivity in the x-direction and the y-direction, the plate has a second thermal conductivity in a z-direction perpendicular to the x direction and the y direction, and the first thermal conductivity is at least 100 times the second thermal conductivity.

The at least one fluid passageway is oriented in the y-direction, the plate has a first thermal conductivity in the y-direction and a z-direction perpendicular to the x direction and the y direction, the plate has a second thermal conductivity in the x-direction, and the first thermal conductivity is at least 100 times the second thermal conductivity.

The at least one fluid passageway is oriented in the y-direction, the plate has a first thermal conductivity in the x-direction and a z-direction perpendicular to the x direction and the y direction, the plate has a second thermal conductivity in the y-direction, and the first thermal conductivity is at least 100 times the second thermal conductivity.

The apparatus further comprises a heat source thermally coupled to the top layer of the plate or the bottom layer of the plate.

The apparatus further comprises a thermal bridge between the plate and the heat source, the thermal bridge being any combination of one or more of a heat sink, a heat spreader, a printed circuit board, a standoff, and a rail.

The heat source is an electronic component capable of generating heat.

The apparatus further comprises a pump attached to the plate and configured to pump fluid through the least one fluid passageway.

In aspects of the present invention, an apparatus comprises a pipe configured to transport a fluid and made of pyrolytic graphite, and a plurality of fins on the pipe, each fin configured to dissipate heat from the pipe.

Any one or a combination of two or more of the following features can be appended to the aspect above to form additional aspects of the invention.

Each fin is made of aluminum, copper, other metal, or material other than pyrolitic graphite.

The pipe has a central axis, each fin has a first thermal conductivity in a radial direction perpendicular to the central axis and a second thermal conductivity in an axial direction parallel to the central axis, and the first thermal conductivity is at least 100 times the second thermal conductivity.

The apparatus further comprises a heat source thermally coupled to the pipe.

The apparatus further comprises a thermal bridge between the pipe and the heat source, the thermal bridge being any combination of one or more of a heat sink, a heat spreader, a printed circuit board, a standoff, and a rail.

The heat source is an electronic component capable of generating heat.

The apparatus further comprises a pump attached to the pipe and configured to pump fluid through the pipe.

The features and advantages of the invention will be more readily understood from the following detailed description which should be read in conjunction with the accompanying drawings.

### BRIEF DESCRIPTION OF THE DRAWINGS

FIGS. 1A to 1C are perspective, front elevation, and side elevation views of a plate for dissipating heat, showing fluid passageways formed between top and bottom layers of the plate;

FIG. 2A is a perspective view of a plate having a greater thermal conductivity in x- and y-directions as compared to that in the z-direction.

FIG. 2B is a cross-section view of the plate taken along lines 2B-2B in FIG. 2A.

FIG. 3A is a perspective view of a plate having a greater thermal conductivity in x- and z-directions as compared to that in the y-direction.

FIG. 3B is a cross-section view of the plate taken along lines 3B-3B in FIG. 3A.

FIG. 4A is a perspective view of a plate having a greater thermal conductivity in y- and z-directions as compared to that in the x-direction.

FIG. 4B is a cross-section view of the plate taken along lines 4B-4B in FIG. 4A.

FIGS. 5 to 8 are perspective views, each showing a plate, heat sources thermally coupled to the plate, and fins thermally coupled to the plate.

FIGS. 9 and 10 are perspective views, each showing a pipe, heat sources thermally coupled to the pipe, and fins thermally coupled to the pipe.

FIG. 11 is a diagram showing a closed loop system for pumping fluid through any of the plates and pipes of FIGS. 1A to 10.

All drawings are schematic illustrations and the structures rendered therein are not intended to be in scale. It should be understood that the invention is not limited to the precise arrangements and instrumentalities shown, but is limited only by the scope of the claims.

### DETAILED DESCRIPTION OF EXEMPLARY EMBODIMENTS

As used herein, the phrase “thermally coupled” refers to a physical heat conduction path from a first structure to a second structure. The first and second structures can optionally be separated from each other by an intervening structure which provides a physical thermal bridge between the first and second structures.

As used herein, a “planar thermal conductive material” is a material having a greater thermal conductivity in directions that lie on a particular plane or are parallel to that plane, as compared to other directions which do not lie on the plane and are not parallel to the plane.

As used herein, the phrase “oblique angle” refers to an angle between zero and ninety degrees.

As used herein, the phrase “consisting essentially of” limits the structure being modified by the phrase to the specified material(s) and other materials that do not materially affect the basic characteristics of the structure. For example, a structure that consists essentially of planar thermal conductive material may include small amounts of other elements or impurities which still allow the structure to have greater thermal conductivity in directions on or parallel to a-b planes as compared to c-directions.

As used herein, “standard room temperature” is a temperature from 20° C. to 25° C.

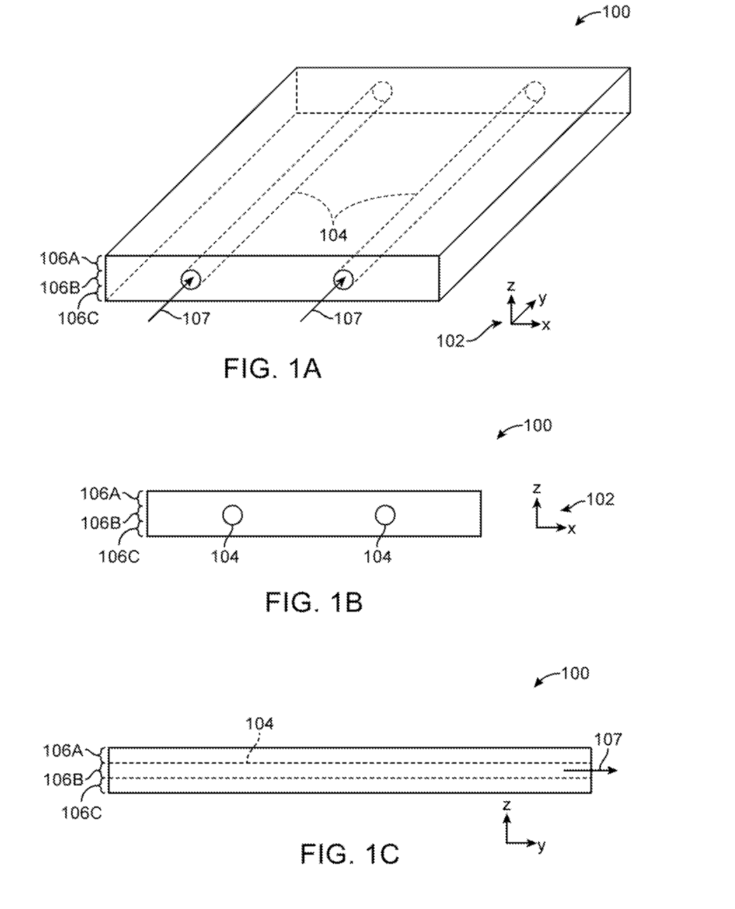

Referring now in more detail to the exemplary drawings for purposes of illustrating embodiments of the invention, wherein like reference numerals designate corresponding or like elements among the several views, there is shown in FIGS. 1A-1C plate 100 for dissipating heat from one or more heat sources. Plate 100 is made of a planar thermal conductive material which provides plate 100 with enhanced thermal conductivity in a particular direction dependent upon the arrangement of atoms in microscopic regions of the material. The directions in which plate 100 has greater thermal conductivity is selected based on how plate 100 will be used. Plate 100 is fabricated from the planar thermal conductive material so as to provide greater thermal conductivity in the pre-selected direction.

Plate 100 can be fabricated from a monolithic piece of the planar thermal conductive material so that plate 100 consists of or consists essentially of an expanse of uninterrupted planar layers of hexagonally arranged carbon atoms. Having uninterrupted planar layers is believed to improve heat dissipation. Alternatively, plate 100 consisting of or consisting essentially of planar thermal conductive material can be fabricated by fastening multiple pieces of the planar thermal conductive material directly to each other.

An example of a suitable planar thermal conductive material is pyrolytic graphite, which provides plate 100 with enhanced thermal conductivity in a particular direction dependent upon the orientation of planar layers of ordered carbon atoms. The carbon atoms of pyrolytic graphite are arranged hexagonally in planes (referred to as a-b planes), which facilitate heat transfer and greater thermal conductivity in directions on the a-b planes. The carbon atoms have an irregular arrangement in directions which do not lie on the a-b plane, which results in diminished heat transfer and lower thermal conductivity in those directions. Thermal conductivity of pyrolytic graphite in directions on a-b planes can be more than four times the thermal conductivity of copper and natural graphite, and more than five times the thermal conductivity of beryllium oxide. Thermal conductivity of pyrolytic graphite for use in any of the embodiments described herein can be in the range of 304 W/m-K to 1700 W/m-K in directions on a-b planes, and 1.7 W/m-K and 7 W/m-K in directions (referred to as c-directions) perpendicular to the a-b planes. The thermal conductivity values are those at standard room temperature. Pyrolytic graphite having these characteristics can be obtained from Pyrogenics Group of Minteq International Inc. of Easton, Pa., USA.

The compositional purity of the planar thermal conductive material will affect thermal conductivity. In some embodiments, plate 100 is constructed such that its thermal conductivity in a first direction corresponding to a-b planes of pyrolytic graphite is at least 100 times or at least 200 times that in a second direction corresponding to a c-direction.

Fluid passageways 104 are through-holes formed through plate 100 and are configured to convey a fluid through the center of plate 100. The fluid can absorb and remove heat from plate 100 as the fluid moves through plate 100. Examples of fluid that can be used include without limitation air, other gases, water, and other liquids. Fluid passageways 104 are disposed between top layer 106A and bottom layer 106C of plate 100. Top layer 106A and bottom layer 106C are made of a planar thermal conductive material such as pyrolytic graphite. Fluid passageways 104 extend through intermediate layer 106B between the top and bottom layers 106A, 106C. Intermediate layer 106B is made of a planar thermal conductive material such as pyrolytic graphite.

Fluid passageways 104 can be formed by drilling a hole into the planar thermal conductive material or joining multiple pieces of the planar thermal conductive material so as to form an empty channel between the pieces. The empty channel which forms the fluid passageway can be straight or have bends. Fluid passageways 104 may optionally include a pipe made of metal or other material which is inserted into the hole or channel in the planar thermal conductive material. Plate 100 is illustrated with two fluid passageways which extend through the entire length of plate 100. Alternatively, only one or a greater number of fluid passageways can be present in plate 100.

In the various figures herein, orthogonal axes 102 indicate the x-, y-, and z-directions relative to plate 100. The x-direction is coplanar with and perpendicular to the y-direction. The z-direction is perpendicular to the x- and y-directions. The x- and y-directions define the x-y plane, the x- and z-directions define the x-z plane, and the y- and z-directions define the y-z plane. Top layer 106A, intermediate layer 106B, and bottom layer 106C are oriented in the x- and y-directions and have thicknesses in the z-direction.

In FIGS. 1A to 8, fluid passageways 104 are axially oriented in the y-direction. The direction of fluid flow is indicated by arrows 107 on the central axis of fluid passageways 104. The central axis of fluid passageways 104 and the direction of fluid flow are parallel to the y-direction. Alternatively, fluid passageways 104 and the direction of fluid flow can be oriented in the x-direction, z-direction, or at an oblique angle to any of the x-, y-, and z-directions. In other embodiments, fluid flow in one passageway can be in an opposite direction as that of fluid flow in another passageway.

The a-b planes of pyrolytic graphite can be oriented parallel to the x-y plane, x-z plane, or the y-z plane. The a-b planes of pyrolytic graphite can also be oriented at any oblique angle to any one or more of the x-y plane, the x-z plane, and the y-z plane.

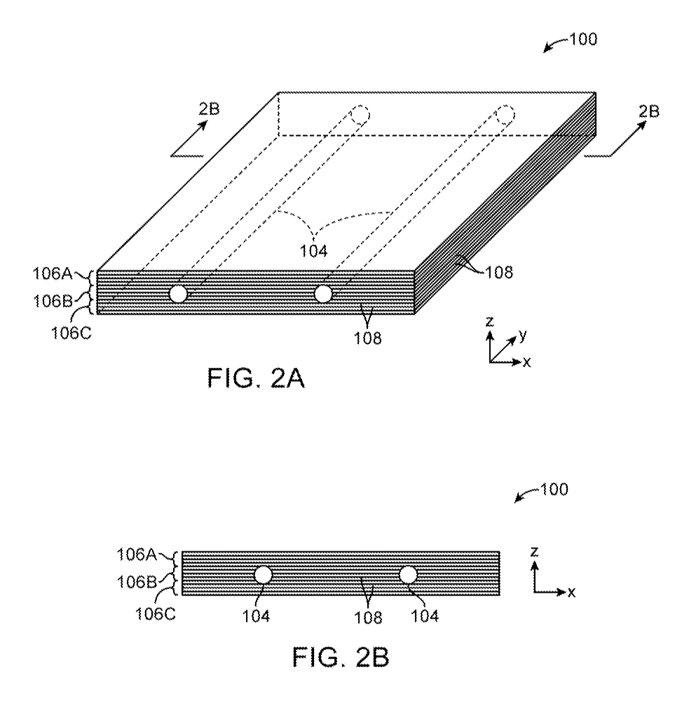

FIGS. 2A to 4B illustrate different orientations for the a-b planes relative to direction 107 of fluid flow in the y-direction. Edges 108 of the a-b planes are illustrated with parallel straight lines to indicate the orientation of the a-b planes. It is to be understood that the a-b planes are microscopic.

In FIGS. 2A and 2B, the a-b planes of pyrolytic graphite in plate 100 are oriented parallel to the x-y plane. Carbon atoms are arranged hexagonally in planar layers oriented in the x- and y-directions. Carbon atoms are arranged irregularly in the z-direction.

In some embodiments, plate 100 has a first thermal conductivity in the x- and y-directions, and a second thermal conductivity in the z-direction. The first thermal conductivity is at least 100 times or at least 200 times the second thermal conductivity.

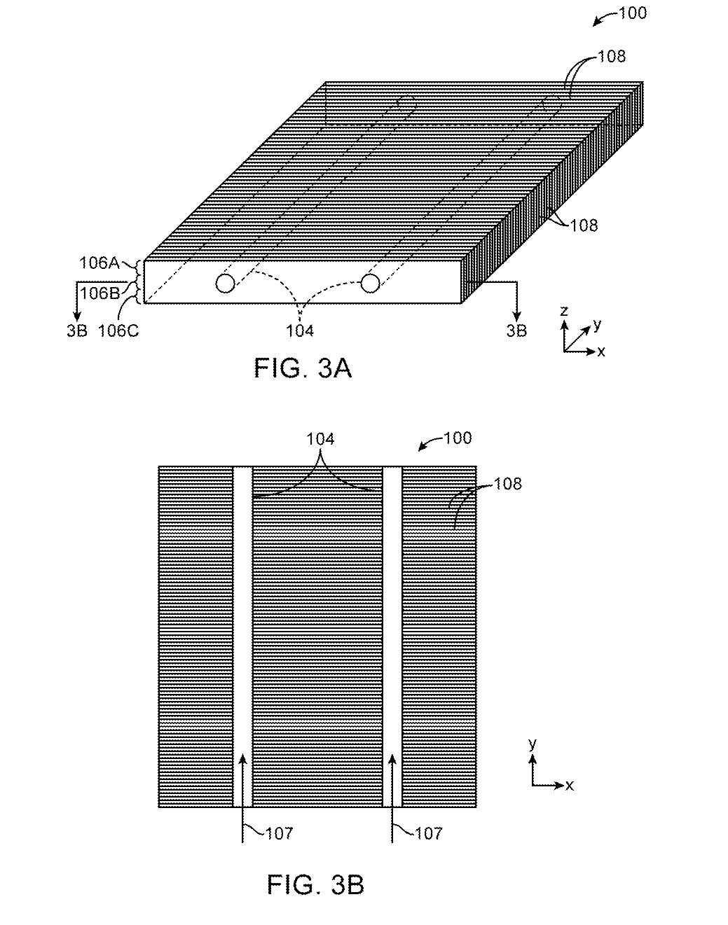

In FIGS. 3A and 3B, the a-b planes of pyrolytic graphite in plate 100 are oriented parallel to the x-z plane. Carbon atoms are arranged hexagonally in planar layers oriented in the x- and z-directions. Carbon atoms are arranged irregularly in the y-direction.

In some embodiments, plate 100 has a first thermal conductivity in the x- and z-directions, and a second thermal conductivity in the y-direction. The first thermal conductivity is at least 100 times or at least 200 times the second thermal conductivity.

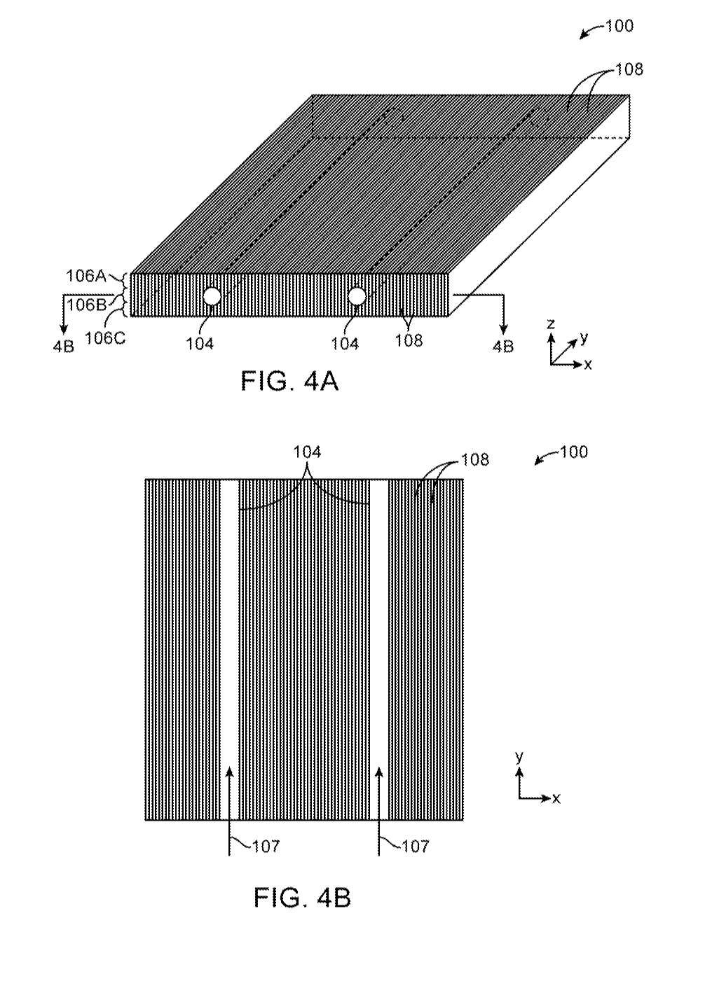

In FIGS. 4A and 4B, the a-b planes of pyrolytic graphite in plate 100 are oriented parallel to the y-z plane. Carbon atoms are arranged hexagonally in planar layers oriented in the y- and z-directions. Carbon atoms are arranged irregularly in the x-direction.

In some embodiments, plate 100 has a first thermal conductivity in the y- and z-directions, and a second thermal conductivity in the x-direction. The first thermal conductivity is at least 100 times or at least 200 times the second thermal conductivity.

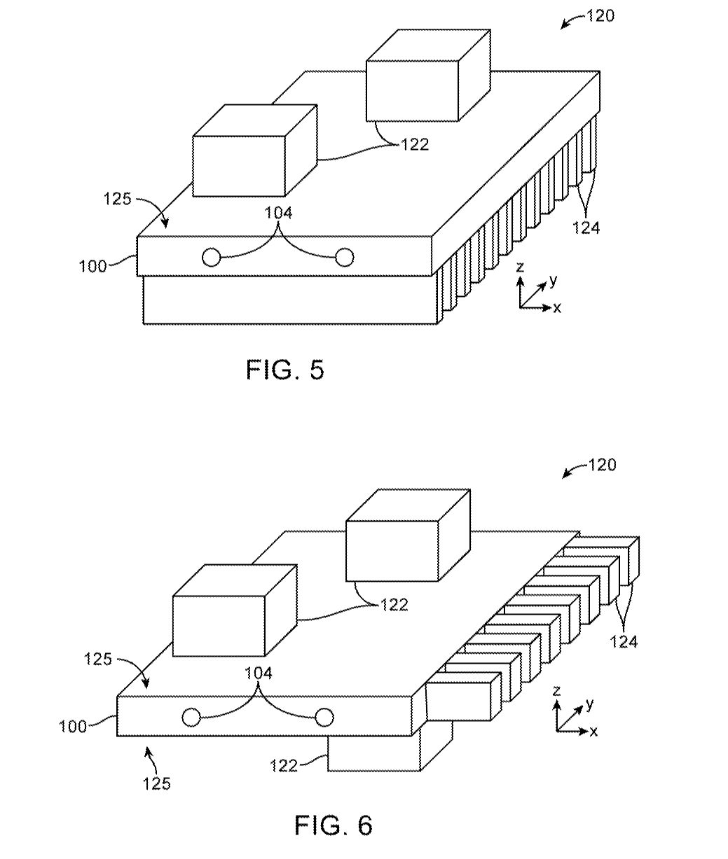

FIGS. 5 to 8 show apparatus 120 comprising plate 100 according to any of the embodiments described above. Apparatus 120 optionally comprises one or more heat sources 122 thermally coupled to one or more sides of plate 100. Plate 100 absorbs and removes heat generated by heat sources 122. Examples of heat sources include without limitation electric power assemblies, power convertors, and electronic components. Examples of electronic components include without limitation semiconductors, integrated circuits, transistors, diodes, and combinations thereof.

Apparatus 120 optionally comprises one or more thin, protruding ribs or fins 124 attached to plate 100. Fins 124 are made of aluminum, copper, other metal, planar thermal conductive material, such as pyrolytic graphite. Fins 124 can be made of a material other than pyrolytic graphite. Fins 124 provide additional surface area for dissipating heat. One or more fluid passageways 104 are optionally formed through the center of plate 100. Fins 124 can be added to plate 100 and fastened in place by bonding or by a mechanical fastener. The a-b planes in fins 124 can be oriented in the same or different direction as the a-b planes in plate 100.

Alternatively, fins 124 can be an integral part of plate 100 and are formed by removing material from a single piece of planar thermal conductive material. Having fins 124 which are integral to plate 100 allows for a region of hexagonally arranged carbon atoms of pyrolytic graphite to extend uninterrupted from plate 100 to fins 124 and thereby improve heat dissipation.

FIGS. 5 to 8 show heat sources 122 thermally coupled to plate 100. Heat sources 122 are optionally fastened directly to plate 100 or optionally fastened indirectly to plate 100 by an intervening structure.

FIGS. 5 and 6 show heat sources 122 fastened directly to plate 100. Direct fastening can be accomplished by bonding and/or a mechanical fastener. For example, heat sources 122 can be bonded directly to flat surfaces 125 on opposite sides of plate 100 by solder, an epoxy, an adhesive, and/or a thermal interface material. A thin layer of solder, epoxy, adhesive, and/or a thermal interface material can be disposed between heat sources 122 and plate 100. A solder, epoxy, and adhesive can be thermal interface materials. Thermal interface materials are capable of filling in air gaps and small surface irregularities in order to lower thermal resistance and improve heat transfer. Examples of thermal interface materials include without limitation thermal grease, gels, epoxies, putty materials, pastes, foils, films, and pads. Heat sources 122 can also be fastened directly to plate 100 by a mechanical fastener that urges heat sources 122 toward plate 100. Examples of mechanical fasteners include without limitation screws, bolts, threaded inserts, clips, clamps, cables, straps, and combinations thereof. One or more holes or recesses may be formed into plate 100 to engage a mechanical fastener.

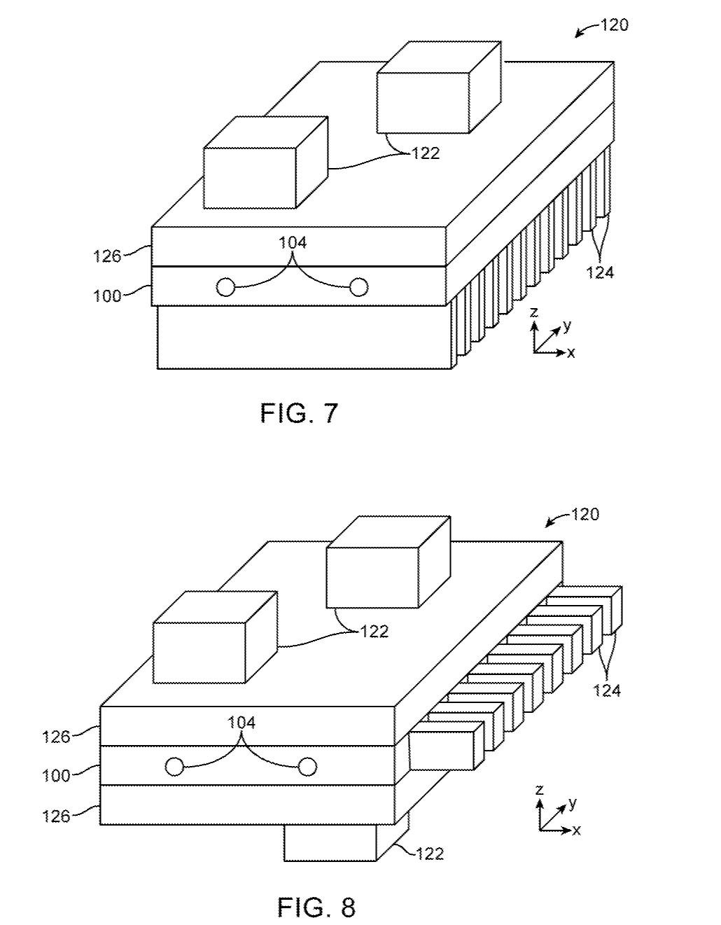

FIGS. 7 and 8 show heat sources 122 fastened indirectly to plate 100 by intervening structures 126 disposed between heat sources 122 and plate 100. Intervening structures 126 provide an indirect connection between heat sources 122 and plate 100. Intervening structures 126 are conceptually illustrated as a single rectangular block. It is to be understood that the shape and size of intervening structure 126 can differ from the illustrated block, and each illustrated block may include one or more discrete components that form a thermal bridge that thermally couples heat sources 122 to plate 100. Heat generated by heat sources 122 is conducted to plate 100 by one or more discrete components of intervening structure 126. Examples of discrete components include without limitation any combination of one or more of a heat sink, a heat spreader, a printed circuit board, a standoff, and a rail. Intervening structures 126 are optionally fastened to plate 100. Fastening of intervening structures 126 to plate 100 can be accomplished by bonding and/or a mechanical fastener, such as disclosed for FIGS. 5 and 6.

It is to be understood that heat sources 122 can be thermally coupled to plate 100 without any fastening. For example, heat sources 122 can rest on plate 100 without being fastened to plate 100. Also, heat sources 122 can rest on top of intervening structure 126 without being fastened to intervening structure 126. Furthermore, intervening structure 126 can rest on top of plate 100 without being fastened to plate 100.

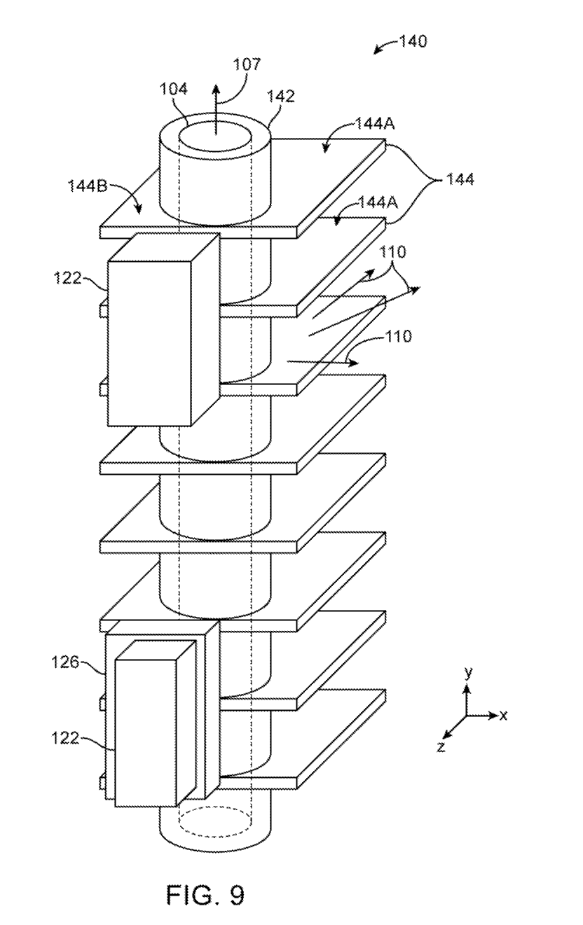

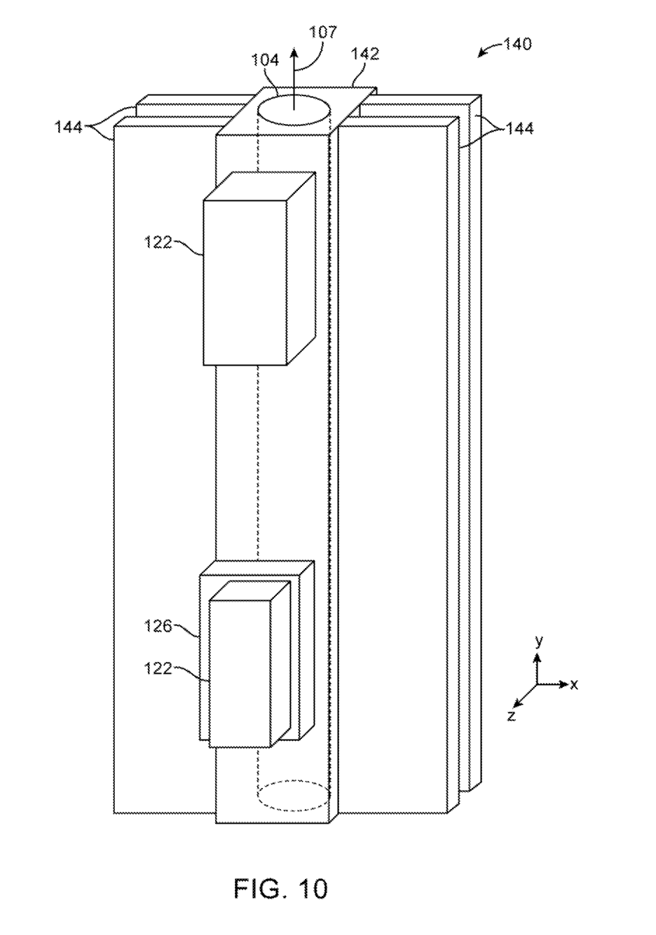

FIGS. 9 and 10 show apparatus 140 for dissipating heat from one or more heat sources 122. Apparatus 140 comprises pipe 142 and a plurality of fins 144 thermally coupled to pipe 142. Fins 144 project radially outward from an outer surface of pipe 142. Fins 144 are made of aluminum, copper, other metal, or planar thermal conductive material such as pyrolytic graphite. Fins 144 can be made of a material other than pyrolytic graphite. Pipe 142 is an elongate tube having a through hole which forms fluid passageway 104. Fluid passageway 104 runs through the entire length of pipe 142. The central axis of fluid passageway 104 and the direction of fluid flow are parallel to the y-direction. Pipe 142 is configured to transport fluid and can be made of copper, aluminum, beryllium oxide, or other thermally conductive material. Pipe 142 can also be made of planar thermal conductive material such as pyrolytic graphite.

Pipe 142 and fins 144 consisting of or consisting essentially of pyrolytic graphite can be fabricated from a monolithic piece of pyrolytic graphite, which would allow for regions of hexagonally arranged carbon atoms to extend uninterrupted from pipe 142 to fins 144 and thereby improve heat dissipation. Alternatively, pipe 142 and fins 144 consisting of or consisting essentially of pyrolytic graphite can be fabricated by joining multiple pieces of the planar thermal conductive material directly to each other. By joining pieces together, the a-b planes in fins 144 can be oriented in the same or different direction as the a-b planes in pipe 142.

For fins 144 and/or pipe 142, the a-b planes of pyrolytic graphite can be oriented parallel to the x-y plane, x-z plane, or the y-z plane. The a-b planes of pyrolytic graphite can also be oriented at any oblique angle to any one or more of the x-y plane, the x-z plane, the y-z plane.

In some embodiments, the a-b planes are perpendicular to the direction of fluid flow indicated by arrow 107 on the central axis of fluid passageway 104. Fin has a first thermal conductivity in one or more radial directions 110 perpendicular to the central axis and a second thermal conductivity in axial direction 112 parallel to the central axis. Optionally, the first thermal conductivity is at least 100 times or at least 200 times the second thermal conductivity.

Heat sources 122 are thermally coupled to pipe 142 and/or fins 144. Pipe 142 is configured to absorb and remove of heat from heat sources 122. Fluid flowing through pipe 142 will absorb and carry away heat from pipe 142. Fins 144 are thermally coupled to pipe 142. When pipe 142 is disposed between heat source 122 and portions 144A (FIG. 9) of fins 144, portions 144A will absorb and dissipate heat from pipe 142. When portions 144B (FIG. 9) of fins 144 are disposed between heat sources 122 and pipe 142, portions 144B will conduct heat from heat sources 144 to pipe 142.

Heat sources 122 are optionally fastened directly to pipe 142 and/or fins 144. Fastening of heat sources 122 can be accomplished by bonding and/or a mechanical fastener, such as disclosed for FIGS. 5 and 6. Heat sources 122 can be thermally coupled to pipe 142 and/or fins 144 without any fastening.

Intervening structures 126 can provide an indirect connection and thermal bridge between heat sources 122 and pipe 142 and/or between heat source 122 and fins 144. Intervening structures 126 are conceptually illustrated as a single rectangular block. It is to be understood that the shape and size of intervening structures 126 can differ from the illustrated block, and the illustrated block may include one or more discrete components that form a thermal bridge that thermally couples one or more heat sources 122 to pipe 142 and/or to fins 144. Examples of discrete components include without limitation those described for FIGS. 7 and 8.

Intervening structure 126 is optionally fastened to pipe 142 and/or fins 144. Heat sources 122 are optionally fastened to intervening structure 126. Fastening can be accomplished by bonding and/or a mechanical fastener, such as disclosed for FIGS. 5 and 6.

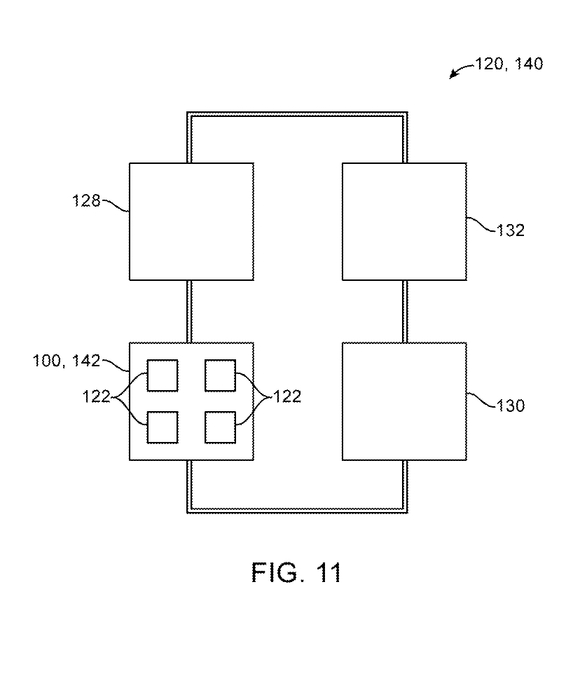

As shown in FIG. 11, any of apparatus 120 and 140 optionally include(s) pump 128 configured to move fluid through one or more fluid passageways of plate 100 or pipe 142. Pump 128 can be attached directly to a fluid passageway of plate 100 or pipe 142 or attached indirectly to a fluid passageway of plate 100 or pipe 142 by a tube which delivers fluid to plate 100 or pipe 142. Plump 128 moves fluid in a closed loop, meaning that fluid is recirculated. Fluid that exits plate 100 or pipe 142 is eventually pumped back into plate 100 or pipe 142. Any of apparatus 120 and 140 optionally include(s) heat exchanger 130 which receives fluid from plate 100 or pipe 142. Heat exchanger 130 is configured to cool the fluid before the fluid is pumped back into plate 100 or pipe 142. Any of apparatus 120 and 140 optionally include(s) reservoir 132 that serves as a storage buffer for the fluid. Reservoir 132 receives cooled fluid from heat exchanger 130 and subsequently provides the cooled fluid to pump 128.

While several particular forms of the invention have been illustrated and described, it will also be apparent that various modifications can be made without departing from the scope of the invention. It is also contemplated that various combinations or subcombinations of the specific features and aspects of the disclosed embodiments can be combined with or substituted for one another in order to form varying modes of the invention. All variations of the features of the invention described above are considered to be within the scope of the appended claims. It is not intended that the invention be limited, except as by the appended claims.

1. An apparatus for dissipating heat, the apparatus comprising:
a plate made of a planar thermal conductive material, the plate including a top layer and a bottom layer, each of the top and bottom layers oriented in an x-direction and a y-direction coplanar with the x-direction, there being at least one fluid passageway formed through the plate and disposed between the top layer and the bottom layer, the at least one fluid passageway configured to transport a fluid.

2. The apparatus of claim 1, wherein the top layer is made of the planar thermal conductive material.

3. The apparatus of claim 1, wherein the bottom layer is made of the planar thermal conductive material.

4. The apparatus of claim 1, wherein the plate includes an intermediate layer between the top layer and the bottom layer, the intermediate layer is made of the planar thermal conductive material, and the at least one fluid passageway extends through the intermediate layer.

5. The apparatus of claim 1, wherein the planar thermal conductive material is pyrolytic graphite.

6. The apparatus of claim 1, further comprising fins on the plate.

7. The apparatus of claim 1, wherein the at least one fluid passageway is oriented in the y-direction, the plate has a first thermal conductivity in the x-direction and the y-direction, the plate has a second thermal conductivity in a z-direction perpendicular to the x-direction and the y-direction, and the first thermal conductivity is at least 100 times the second thermal conductivity.

8. The apparatus of claim 1, wherein the at least one fluid passageway is oriented in the y-direction, the plate has a first thermal conductivity in the y-direction and a z-direction perpendicular to the x-direction and the y-direction, the plate has a second thermal conductivity in the x-direction, and the first thermal conductivity is at least 100 times the second thermal conductivity.

9. The apparatus of claim 1, wherein the at least one fluid passageway is oriented in the y-direction, the plate has a first thermal conductivity in the x-direction and a z-direction perpendicular to the x-direction and the y-direction, the plate has a second thermal conductivity in the y-direction, and the first thermal conductivity is at least 100 times the second thermal conductivity.

10. The apparatus of claim 1, further comprising a heat source thermally coupled to the top layer of the plate or the bottom layer of the plate.

11. The apparatus of claim 10, further comprising a thermal bridge between the plate and the heat source, the thermal bridge being any combination of one or more of a heat sink, a heat spreader, a printed circuit board, a standoff, and a rail.

12. The apparatus of claim 10, wherein the heat source is an electronic component capable of generating heat.

13. The apparatus of claim 1, further comprising a pump attached to the plate and configured to pump fluid through the least one fluid passageway.

14. An apparatus for dissipating heat, the apparatus comprising:
a pipe configured to transport a fluid and made of pyrolytic graphite; and
a plurality of fins on the pipe, each fin configured to dissipate heat from the pipe.

15. The apparatus of claim 14, wherein each fin is made of aluminum, copper, other metal, or material other than pyrolytic graphite.

16. The apparatus of claim 14, wherein the pipe has a central axis, each fin has a first thermal conductivity in a radial direction perpendicular to the central axis and a second thermal conductivity in an axial direction parallel to the central axis, and the first thermal conductivity is at least 100 times the second thermal conductivity.

17. The apparatus of claim 14, further comprising a heat source thermally coupled to the pipe.

18. The apparatus of claim 17, further comprising a thermal bridge between the pipe and the heat source, the thermal bridge being any combination of one or more of a heat sink, a heat spreader, a printed circuit board, a standoff, and a rail.

19. The apparatus of claim 17, wherein the heat source is an electronic component capable of generating heat.

20. The apparatus of claim 14, further comprising a pump attached to the pipe and configured to pump fluid through the pipe.
